(19) United States
(12) Patent Application Publication
(10) Pub. No.: US 2025/0379201 A1
(43) Pub. Date: Dec. 11, 2025

(54) CIRCUITS FOR CONNECTING HIGH-BANDWIDTH MEMORY CUBES TO A HOST DEVICE, AND ASSOCIATED SYSTEMS AND METHODS

(71) Applicant: Micron Technology, Inc., Boise, ID (US)

(72) Inventors: Raghukiran Sreeramaneni, Frisco, TX (US); Nevil N. Gajera, Meridian, ID (US)

(21) Appl. No.: 19/221,430

(22) Filed: May 28, 2025

Related U.S. Application Data
(60) Provisional application No. 63/658,279, filed on Jun. 10, 2024.

(51) Int. Cl. H01L 25/18; H01L 23/00; H10B 80/00; H10D 80/30

(52) U.S. Cl. CPC H01L 25/18; H10B 80/00; H10D 80/30; H01L 24/16; H01L 2224/16145; H01L 2224/16225; H01L 2225/06513; H01L 2225/06541; H01L 2924/1431; H01L 2924/1436

(57) ABSTRACT

System-in-package (“SiP”) devices, and associated systems and methods, are disclosed herein. The SiP device can include an interposer, a host device, and a plurality of high-bandwidth memory (“HBM”) cubes. A first set of the HBM cubes can be positioned around a perimeter of the host device and coupled to the host device through the interposer. A second set of the HBM cubes can be positioned peripheral to the first set with respect to the host device. The HBM cubes of the second set can be coupled to the host device through a footprint of one or more the HBM cubes of the first set, such as through communication circuits in base dies of the HBM cubes of the first set and/or communication circuits formed in the interposer and/or positioned beneath the HBM cubes of the first set.

### CROSS-REFERENCE TO RELATED APPLICATION(S)

The present application claims priority to U.S. Provisional Patent Application No. 63/658,279, filed Jun. 10, 2024, the disclosure of which is incorporated herein by reference in its entirety.

### TECHNICAL FIELD

The present technology is generally related to semiconductor devices. For example, several embodiments of the present technology relate to connecting one or more high-bandwidth memory cubes to a host device through footprints of other high-bandwidth memory cubes (e.g., to expand the number of high-bandwidth memory cubes coupled to the host device).

### BACKGROUND

An electronic apparatus (e.g., a processor, a memory device, a memory system, or a combination thereof) can include one or more semiconductor circuits configured to store and/or process information. For example, the apparatus can include a memory device, such as a volatile memory device, a non-volatile memory device, or a combination device. Memory devices, such as dynamic random-access memory (DRAM) and/or high-bandwidth memory (HBM), can utilize electrical energy to store and access data.

With technological advancements in embedded systems and increasing applications, the market is continuously looking for faster, more efficient, and smaller devices. To meet the market demands, the semiconductor devices are being pushed to the limit with various improvements. Improving devices, generally, may include increasing circuit density, increasing circuit capacity, increasing operating speeds (or otherwise reducing operational latency), increasing reliability, increasing data retention, reducing power consumption, or reducing manufacturing costs, among other metrics. Attempts, however, to meet the market demands, such as by reducing the overall device footprint, can often introduce challenges in other aspects, such as maintaining circuit robustness and/or failure detectability.

### BRIEF DESCRIPTION OF THE DRAWINGS

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to the specific embodiments depicted, but are for explanation and understanding only.

FIGS. 1A and 1B are a partially schematic cross-sectional view and a partially schematic top plan view, respectively, of a system-in-package device.

FIG. 2 is a partially schematic top plan view of a system-in-package device configured in accordance with various embodiments of the present technology.

FIG. 3A is a partially schematic top plan view of an interface die of a high-bandwidth memory cube configured in accordance with various embodiments of the present technology.

FIG. 3B is a partially schematic top plan view of a system-in-package device with high- bandwidth memory cubes of the type illustrated in FIG. 3A, in accordance with various embodiments of the present technology.

FIG. 4A is a partially schematic top plan view of a cube region of an interposer of a system-in-package device configured in accordance with various embodiments of the present technology.

FIG. 4B is a partially schematic top plan view of a system-in-package device with a plurality of cube regions of the type illustrated in FIG. 4A, in accordance with various embodiments of the present technology.

### DETAILED DESCRIPTION

As discussed in more detail below, the present disclosure is directed to expanding the number of high-bandwidth memory (HBM) cubes that can be coupled to a host device within a system-in-package (SiP) device. For example, several embodiments of the present technology discussed herein are directed to SiP devices in which one or more HBM cubes (sometimes also referred to herein as “HBM devices”) are connected to a host device through a footprint of another HBM cube. In one specific example, a SiP device of the present technology includes a first set of the HBM cubes in which each HBM cube of the first set has a communication circuit (e.g., in its base die or at another location) that facilitates routing signals (e.g., read/write signals) between HBM cubes of a second set and a host device. In another specific example, a SiP device of the present technology includes an interposer that has communication circuits that are formed at least partially in the interposer (e.g., in areas located beneath a first set of HBM cubes), and that facilitate routing signals between HBM cubes of a second set and a host device. The communication circuits in one or both of the specific examples above may additionally be used to route signals between the host device and memory dies included within the HBM cubes of the first set. As such, rather than being limited to a number of HBM cubes that can be positioned immediately about a perimeter of a host device (and/or on top of the host device), the present technology permits a greater number of HBM cubes to be communicably coupled to the host device. In turn, the present technology facilitates expanding an amount of memory available to the host device via a high-bandwidth communication channel.

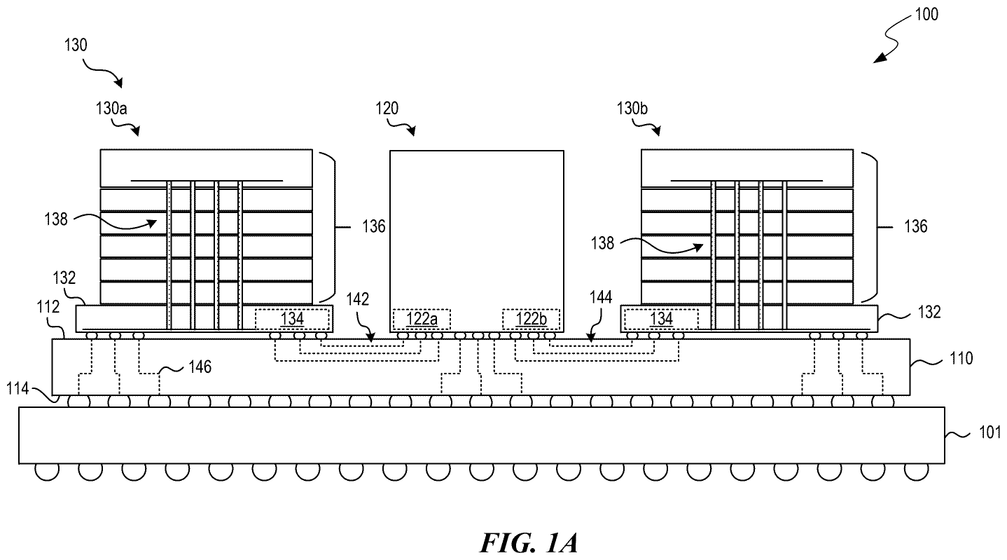

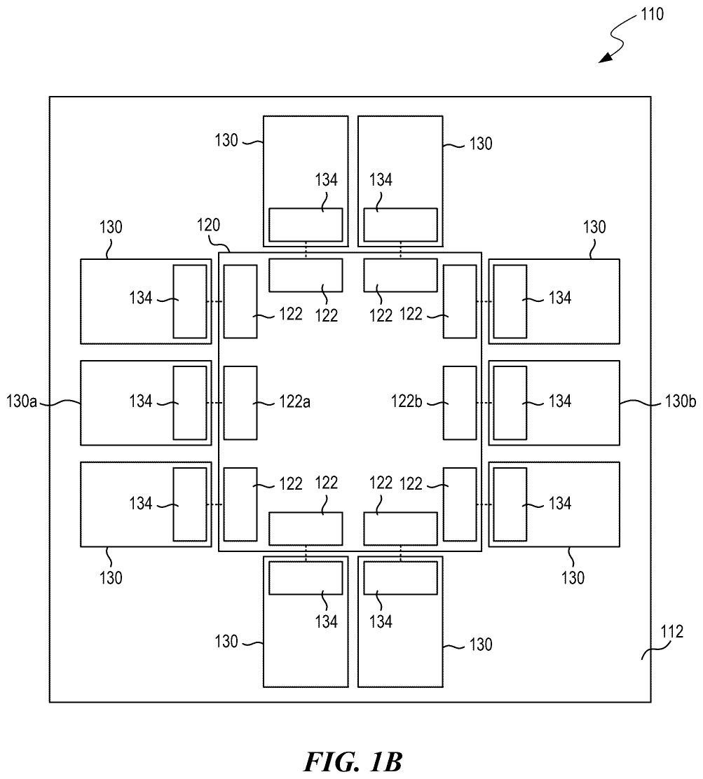

Specific details of several embodiments of the present technology are described herein with reference to FIGS. 1A-4B. For the sake of clarity and example, the present technology is primarily described below in the context of SiP devices incorporating high-bandwidth memory devices, such as high-bandwidth memory cubes that each include a plurality of memory dies (e.g., arranged in one or more stacks and/or positioned laterally adjacent one another). The memory dies are primarily described below in the context of dies incorporating volatile storage elements, such as dynamic random-access memory (DRAM) storage elements. Memory dies configured in accordance with other embodiments of the present technology, however, can include other types of storage elements (e.g., in addition to or in lieu of DRAM storage elements), such as other types of volatile storage elements (e.g., static random-access memory (SRAM) storage elements) and/or non-volatile storage elements (e.g., NAND, NOR, phase change memory (PCM), ferroelectric random-access memory (FeRAM), resistive random-access memory (RRAM), and magnetic random-access memory (MRAM), among others). Additionally, or alternatively, SiP devices configured in accordance with other embodiments of the present technology can incorporate other types of memory devices (e.g., hybrid memory cubes) in addition to or in lieu of high-bandwidth memory devices/cubes.

Furthermore, although interconnection mechanisms (e.g., communication circuits) employed in SiP devices of the present technology are primarily described herein as interconnecting a plurality of high-bandwidth memory cubes to one another and/or to a host device, it will be understood that interconnection mechanisms of the present technology can also be utilized to connect various other structures/components to one another and/or to a host device. Additionally, or alternatively, although primarily discussed herein as relevant to connecting a greater number of HBM cubes to a host device to facilitate executing artificial intelligence and/or machine learning algorithms (e.g., more quickly), one of skill in the art will understand that the scope of the invention is not so limited. For example, several of the SiP devices described herein can also be used for various other data-intensive computer operations, such as video rendering, high-resolution graphics applications, and/or various other computing applications. Moreover, a person of ordinary skill in the art will understand that embodiments of the present technology can have different configurations, components, and/or procedures than those shown or described herein, and/or that these and other embodiments can be without several of the configurations, components, and/or procedures shown or described herein without deviating from the present technology.

As used herein, the terms “vertical,” “lateral,” “upper,” “lower,” “top,” and “bottom” can refer to relative directions or positions of features in the SiP devices in view of the orientation shown in the drawings. For example, “bottom” can refer to a feature positioned closer to the bottom of a page than another feature. These terms, however, should be construed broadly to include SiP devices having other orientations, such as inverted or inclined orientations where top/bottom, over/under, above/below, up/down and left/right can be interchanged depending on the orientation.

High data reliability, high speed of memory access, lower power consumption, and reduced chip size are features that are demanded from semiconductor memory. In recent years, three-dimensional (3D) memory devices have been introduced. Some 3D memory devices are formed by stacking memory dies vertically, and interconnecting the dies using through-silicon (or through-substrate) vias (TSVs). Benefits of the 3D memory devices include shorter interconnects (which reduce circuit delays and power consumption), a large number of vertical vias between layers (which allow wide bandwidth buses between functional blocks, such as memory dies, in different layers), and a considerably smaller footprint. Thus, the 3D memory devices contribute to higher memory access speed, lower power consumption, and chip size reduction. Example 3D memory devices include hybrid memory cubes (HMC) and high-bandwidth memory (HBM) devices. For example, HBM is a type of memory that includes a vertical stack of memory dies (e.g., dynamic random-access memory (DRAM) dies) and an interface die (which, e.g., provides an interface between the memory dies of the HBM device and a host device).

In a typical SiP configuration, HBM devices may be integrated with a host device (e.g., a graphics processing unit (GPU), a computer processing unit (CPU), a tensor processing unit (TPU), and/or any other suitable processing unit) using a base substrate (e.g., a silicon interposer, a substrate of organic material, a substrate of inorganic material, and/or any other suitable material that provides interconnection between the host device and the HBM device and/or provides mechanical support for the components of a SiP device), through which the HBM devices and the host device communicate. Because traffic between the HBM devices and the host device resides within the SiP (e.g., using signals routed through the interposer), a higher bandwidth may be achieved between the HBM devices and the host device than in conventional systems. In other words, the TSVs interconnecting memory dies within an HBM device and route lines in the interposer (sometimes referred to collectively as part of a system bus) enable the routing of a greater number of signals (e.g., wider data buses) than is typically found between packaged memory devices and a host device (e.g., through a printed circuit board (PCB)). The high-bandwidth interface within a SiP enables large amounts of data to move quickly between the host device (e.g., GPU/CPU) and HBM devices during operation. For example, the high-bandwidth channels can be on the order of 1000 gigabytes per second (GB/s, sometimes also referred to as gigabits (Gb)). It will be appreciated that such high-bandwidth data transfer between a host device and memory dies of HBM devices can be advantageous in various high-performance computing applications, such as video rendering, high-resolution graphics applications, artificial intelligence and/or machine learning (AI/ML) computing systems and other complex computational systems, and/or various other computing applications.

FIGS. 1A and 1B are a partially schematic cross-sectional view and a partially schematic top plan view, respectively, of a SiP device 100. As shown, the SiP device 100 can include a interposer 110 (or any other suitable base substrate) that is carried by a package substrate 101 (FIG. 1A). The SiP device 100 also includes a host device 120 and a plurality of HBM cubes 130 (two of which are identified individually as first HBM cube 130a and second HBM cube 130b) each carried by and electrically coupled to (e.g., integrated with) an upper surface 112 of the interposer 110. The host device 120 (e.g., a GPU, CPU, TPU, and/or any other suitable processing unit) can include, among other features, a register and one or more levels of cache (e.g., an L1 cache, an L2 cache, and/or the like). As further illustrated in FIG. 1A, each of the HBM cubes 130 (sometimes also referred to herein as “HBM devices”) can include an interface die 132, one or more memory dies 136 (FIG. 1A) carried by the interface die 132, and one or more through substrate vias 138 (“TSVs 138”; FIG. 1A) coupled to the interface die 132 and each of the memory dies 136. The TSVs 138 allow each of the dies in the HBM cubes 130 to communicate data (e.g., between the memory dies 136 (e.g., DRAM dies) and the interface die 132 (sometimes also referred to herein as a “base die,” a “logic die,” and/or the like) at a relatively high rate (e.g., on the order of 1000 GB/s or greater).

The interface die 132, in turn, can communicate the data to the host device 120. For example, a first host physical layer 122a (“first host PHY 122a”) in the host device 120 is coupled to one or more first route lines 142 (FIG. 1A) formed in the interposer 110. In turn, the first route lines 142 are coupled to an HBM PHY 134 in the first HBM cube 130a. As a result, the interface die 132 in the first HBM cube 130a is communicably coupled to the host device 120. Similarly, a second host PHY 122b in the host device 120 is coupled to one or more second route lines 144 (FIG. 1A) that are, in turn, coupled to an HBM PHY 134 in a second HBM cube 130b. As a result, the interface die 132 in the second HBM cube 130b is communicably coupled to the host device 120. Similar to the TSVs 138 (FIG. 1A), the first and second route lines 142, 144 can provide a high bandwidth (e.g., on the order of 1000 GB/s) channel through the interposer 110. As a result, each of the HBM cubes 130 can expand the amount of memory that is accessible to the host device 120 via a high-bandwidth communication channel.

As illustrated in FIG. 1A, the interposer 110 can further include one or more interposer TSVs 146 extending between the upper surface 112 of the interposer 110 and a lower surface 114 of the interposer 110. The interposer TSVs 146 can allow the host device 120 and/or the HBM cubes 130 to send and/or receive signals (e.g., control signals, instructions, processing results, data, and/or the like) to and/or from, respectively, other devices coupled to the package substrate 101. In a specific, non-limiting example, the interposer TSVs 146 can allow the HBM cubes 130 to receive data from an external storage device (e.g., a NAND device) coupled to the package substrate 101. Accessing data outside of the SiP device 100, however, typically requires the data to travel through a relatively slow communication channel (e.g., a PCI bus with a bandwidth on the order of about 8 GB/s). As a result, accessing data outside of the SiP device 100 can create a bottleneck in the overall processing speed of the SiP device 100.

Although the HBM cubes 130 discussed and illustrated in FIGS. 1A and 1B provide relatively high bandwidth communication, their integration on the interposer 110 suffers from certain shortcomings. For example, each of the HBM cubes 130 provides a limited amount of storage (e.g., on the order of 16 GB each). Further, as illustrated in FIG. 1A, the first and second route lines 142, 144 can only be formed in regions where they do not interfere with the interposer TSVs 146. As a result, the SiP device 100 is limited to positioning the HBM cubes 130 immediately around (fully or partially) a perimeter of the host device 120 (e.g., in “beachfront” locations around the perimeter) and/or on top of the host device 120 to avoid interfering with the interposer TSVs 146. As a result, the total storage provided by all of the HBM cubes 130 has a limit that may be insufficient to maintain a working data set of one or more operations to be performed by the SiP device 100, which can, in some instances, require data to be communicated through the bottleneck discussed above. The limitation can be especially impactful for data-intensive computing operations (e.g., video rendering), high-resolution graphics applications, artificial intelligence and/or machine learning (AI/ML) computing systems and other complex computational systems, and/or the like.

SiP devices (and associated systems and methods) that address the shortcomings discussed above are disclosed herein. As discussed in more detail below, the SiP devices disclosed herein can include an interposer (e.g., a silicon interposer, a substrate of organic material, a substrate of inorganic material, and/or any other suitable material), as well as a host device and a plurality of HBM devices integrated with (e.g., coupled to and/or carried by) an upper surface of the interposer. The plurality of HBM cubes can include at least a first set and second set of HBM cubes. The first set can be positioned around (e.g., about, adjacent, immediately adjacent, proximate) a perimeter of the host device (sometimes referred to herein as “beachfront locations”) while the second set is positioned peripheral to the first set with respect to the host device. That is, the HBM cubes in the first set can be positioned between the second set of HBM cubes and the host device. Said another way, each of the HBM cubes in the second set can be spaced apart from the perimeter of the host device by at least one HBM cube in the first set. While the HBM cubes in the first set can be coupled directly to the host device through the interposer, the HBM cubes in the second set can each be coupled to the host device through a footprint of at least one of the HBM cubes in the first set.

In some embodiments, the HBM cubes in the second set are each coupled to the host device through the HBM cubes in the first set. For example, each of the HBM cubes (e.g., in the first set and/or the second set) can include a base die (e.g., an interface die) and a stack of memory dies (e.g., DRAM dies) carried by the base die. The base die of an HBM cube can include a communication circuit that has a fabric interconnect engine and one or more chip-to-chip (C2C) circuits. The C2C circuits (sometimes also referred to herein as “C2C interconnects”) couple the base die of the HBM cube to an external component, such as a route line formed in the interposer, a component in the host device (e.g., a C2C circuit and/or a physical layer therein), a C2C circuit in a neighboring HBM cube, and/or any other suitable component, to send signals from and receive signals at the HBM cube. The fabric interconnect engine, in turn, can help route the signals through the C2C circuits. For example, the fabric interconnect engine can check an address for a signal received at a first C2C circuit in a base die of an HBM cube. If the address corresponds to the HBM cube of the fabric interconnect engine, the signal can be directed to a physical layer (PHY, e.g., a JEDEC PHY) in the HBM cube. If addressed to another HBM cube, the fabric interconnect engine can forward the signal through the first C2C circuit and/or through a second C2C circuit in the base die of the HBM cube. Accordingly, for example, each HBM cube in the first set described above can forward signals between the host device and one or more HBM cubes in the second set.

In some embodiments, the interposer includes a plurality of communication circuits formed in cube regions under each of the HBM cubes in the first set (e.g., within the footprint of the HBM cubes in the first set). Similar to the discussion above, the communication circuits can each include a fabric interconnect engine and one or more C2C circuits. Further, the communication circuits can receive and route signals through the interposer. For example, the fabric interconnect engine in an individual one of the communication circuits can check the address in a received signal. If the signal is associated with an HBM device integrated with the interposer above the communication circuit, the fabric interconnect engine can forward the signal toward the HBM device (e.g., to a PHY onboard the HBM cube and/or any other suitable component in the HBM cube). In some such embodiments, the communication circuit can include a PHY (e.g., a JEDEC PHY) coupled to the HBM device and the fabric interconnect engine can forward the signal to the PHY in the interposer. In turn, the PHY in the interposer can direct the signal toward an appropriate destination (e.g., a PHY onboard the HBM cube and/or a memory die in the HBM cube). In other such embodiments, the communication circuit can lack a PHY (e.g., a JEDEC PHY) and can direct the signal toward an appropriate destination (e.g., a PHY onboard the HBM cube and/or a memory die in the HBM cube). On the other hand, if the signal is associated with another HBM device (e.g., an HBM device different from the HBM device integrated with the interposer above the communication circuit), the fabric interconnect engine can forward the signal through one of the C2C circuits of the communication circuit toward the appropriate destination (e.g., another communication circuit of the interposer). Accordingly, for example, each HBM cube in the second set described above can be coupled to the host device through one or more communication circuits within the footprint of one or more corresponding HBM cube(s) in the first set.

In some embodiments, the SiP device includes multiple possible communication paths between an individual HBM cube in the second set and the host device. For example, a first path extending between the individual HBM cube and the host device can pass through the footprint of a first HBM cube in the first set while a second path extending between the individual HBM cube and the host device can pass through the footprint of a second HBM cube in the first set. In such embodiments, the first and/or second paths can include the footprint of one or more HBM cubes in the second set (e.g., with communication circuits formed in the interface die of the HBM cubes and/or in the interposer integrated with the HBM cubes). The multiple communication paths can allow, for example, the host device to pick between different communication paths to send or receive data to or from, respectively, the individual HBM cube in the second set. For example, the host device can choose a path based on availability (e.g., selecting the second path when the first path is busy with communications between the first HBM cube and the host device; selecting the first path when the host predicts it will need the second path (or a portion of the second path); and/or the like). Additionally, or alternatively, the host device can choose a path based on an operability of the paths (e.g., choosing the first communication path when one or more components of communication circuits in the second path fail, such as when one or more C2C circuits is/are damaged). In these and other embodiments, the host device can choose a path based on a speed of the available paths (e.g., selecting the first path when the first path includes a single pass through a communication circuit, sometimes referred to herein as a hop, while the second path includes multiple hops such that the first path is generally faster). Additionally, or alternatively, the host device can choose a path based on an energy requirement of the paths (which can depend on, for example, a length of the paths, differences and/or manufacturing defects in various communication circuits, and/or the like).

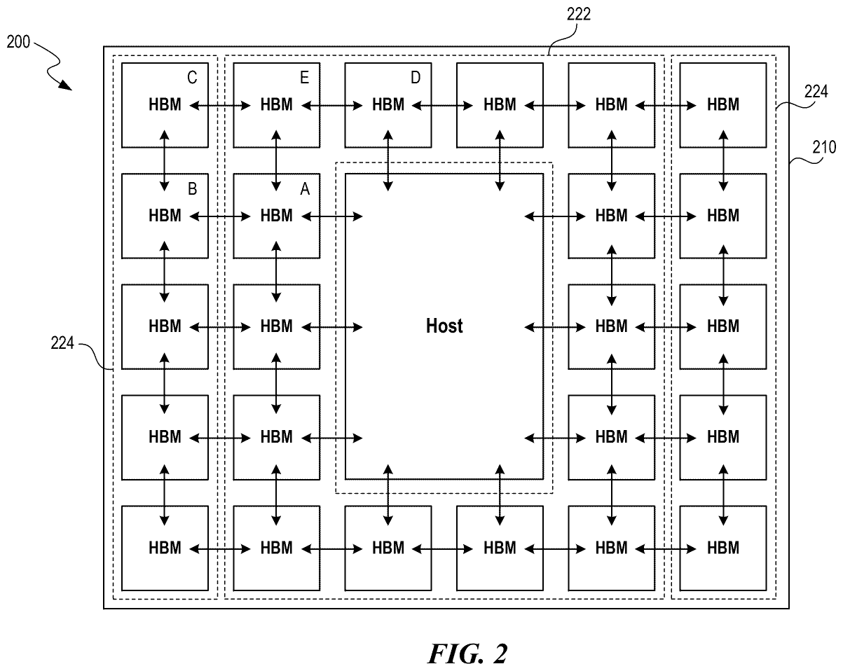

FIG. 2 is a partially schematic top plan view of a SiP device 200 configured in accordance with various embodiments of the present technology. As illustrated in FIG. 2, the SiP device 200 can be generally similar to the SiP device 100 discussed above with reference to FIGS. 1A and 1B. For example, the SiP device 200 can include an interposer 210, as well as a host device (labeled “Host”) and a plurality of HBM cubes (each labeled “HBM”) integrated with (e.g., carried by and/or coupled to) the interposer 210. The interposer 210 can be a silicon interposer, a substrate of organic material, a substrate of inorganic material, and/or any other suitable material to provide an interconnection between the host device and the HBM cubes and/or to provide mechanical support for the components of a SiP device 200.

The SiP device 200 of FIG. 2, however, includes various circuit elements (sometimes referred to collectively herein as “communication circuits,” “traffic circuits,” and/or the like) that are formed in the HBM cubes and/or via the interposer 210 beneath each of the HBM cubes. As a result, the communication circuits allow the HBM cubes to communicate with each other and/or communicate with the host device (e.g., through a footprint of one or more other HBM cubes) such as along one or more of the arrows illustrated in FIG. 2. For example, the SiP device 200 can include a first set 222 of HBM cubes that are positioned around (partially or fully) a perimeter of the host device and a second set 224 of HBM cubes that are positioned around (partially or fully) a perimeter of the first set 222 of HBM cubes. Said another way, the HBM cubes in the first set 222 are integrated with a first region of the interposer 210 immediately adjacent to the host device (and/or immediately adjacent to a processing region of the interposer 210) while the HBM cubes in the second set 224 are integrated with a second region of the interposer 210 peripheral to the first region with respect to the host device (and/or the processing region). Said yet another way, the HBM cubes in the first set 222 are communicably positioned between the HBM cubes in the second set 224 and the host device. As a result, each of the HBM cubes in the first set 222 can be directly coupled to the host device (e.g., in the manner discussed above with reference to FIG. 1A) and/or coupled to the host device through one or more other HBM cubes of the first set 222. Each of the HBM cubes in the second set 224, however, are coupled to the host device through a footprint of at least one of the HBM cubes in the first set 222.

As further illustrated by the arrows in FIG. 2, the communication circuits can allow signals (e.g., read requests, data, and/or the like) to be communicated in a variety of directions. As a result, the host device can communicate with the HBM cubes in the second set 224 via a variety of communication paths through footprints of HBM cubes in the first set 222 and/or the second set 224. For example, to communicate with the upper left HBM cube (labeled C), the host device can send or receive signals via (i) a first communication path that passes through footprints of the HBM cubes labeled A and B, (ii) a second communication path that passes through footprints of the HBM cubes labeled D and E, and/or (iii) a third communication path that passes through footprints of the HBM cubes labeled A and E.

In some embodiments, the variety of communication paths allows the host device to access the HBM cubes in the second set 224 in a flexible and/or non-static manner. For example, the host device can communicate with the HBM cube labeled C through the first path during a first communication session and communicate with the HBM cube labeled C through the third path during a second communication session. In such embodiments, the communication path chosen can be based at least partially on other communications the host device is engaged in. For example, the host device can use the third communication path when the host device is actively communicating with the HBM cube labeled A. The choice can allow the SiP device 200 to avoid multiple communication paths running through the communication circuits within the footprint of the HBM cube labeled A. When multiple communication paths are available, the host device can choose a communication path with a shortest number of hops (e.g., running through the fewest number of communication circuits in (or beneath) the HBM cubes), a largest bandwidth available for the communication, and/or a most efficient communication channel. Additionally, or alternatively, the host device can choose a communication path based at least partially on a prediction of future communications. For example, when the host device knows (or predicts) that it will need to access the HBM cube labeled E in the near future, the host device can choose the first or second communication path to access the HBM cube labeled C. As a result, the host device can reduce (or eliminate) traffic through interconnection circuits before they are needed for access.

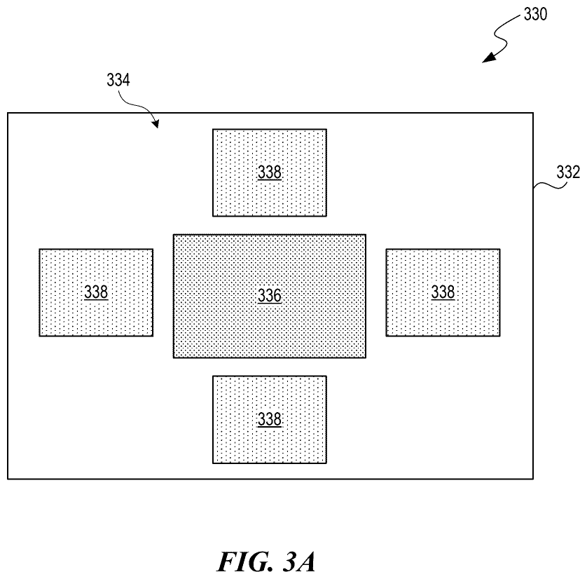

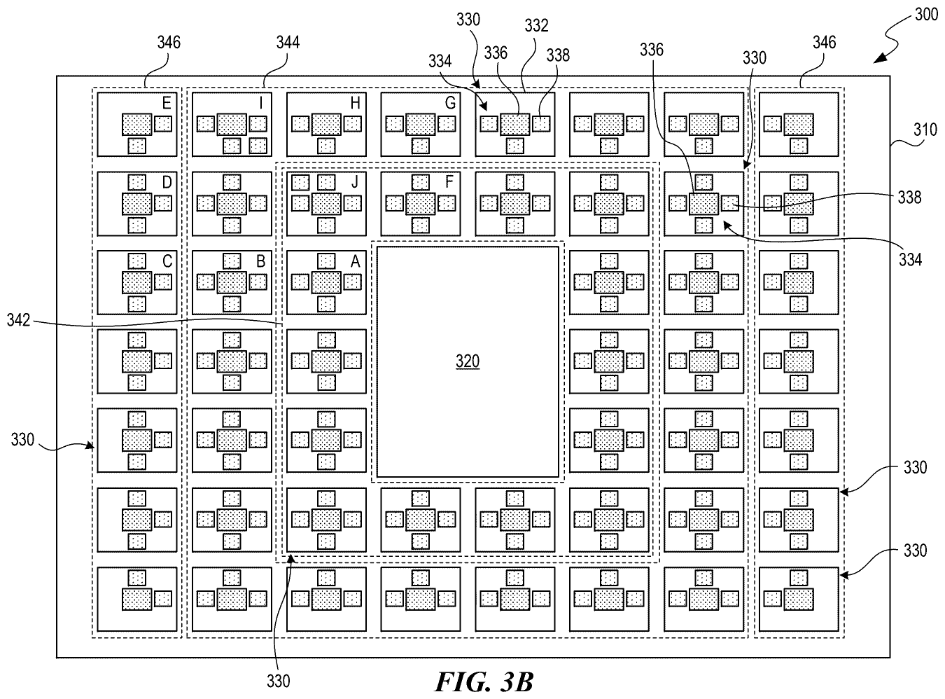

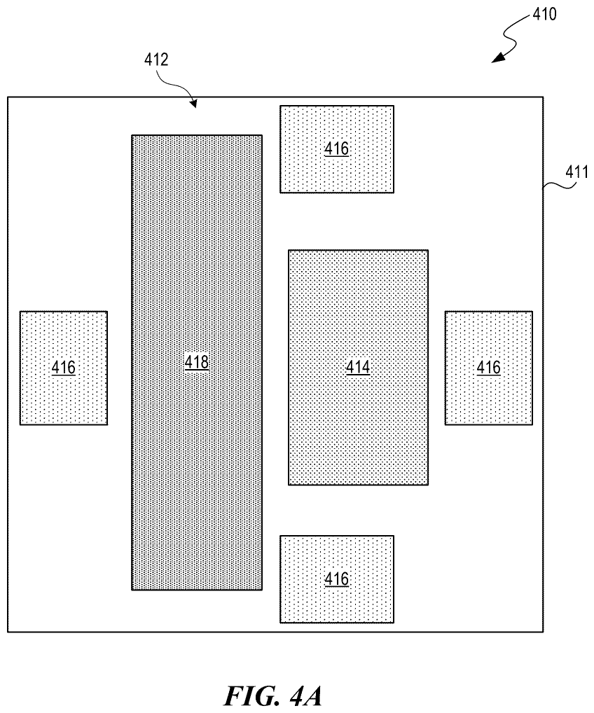

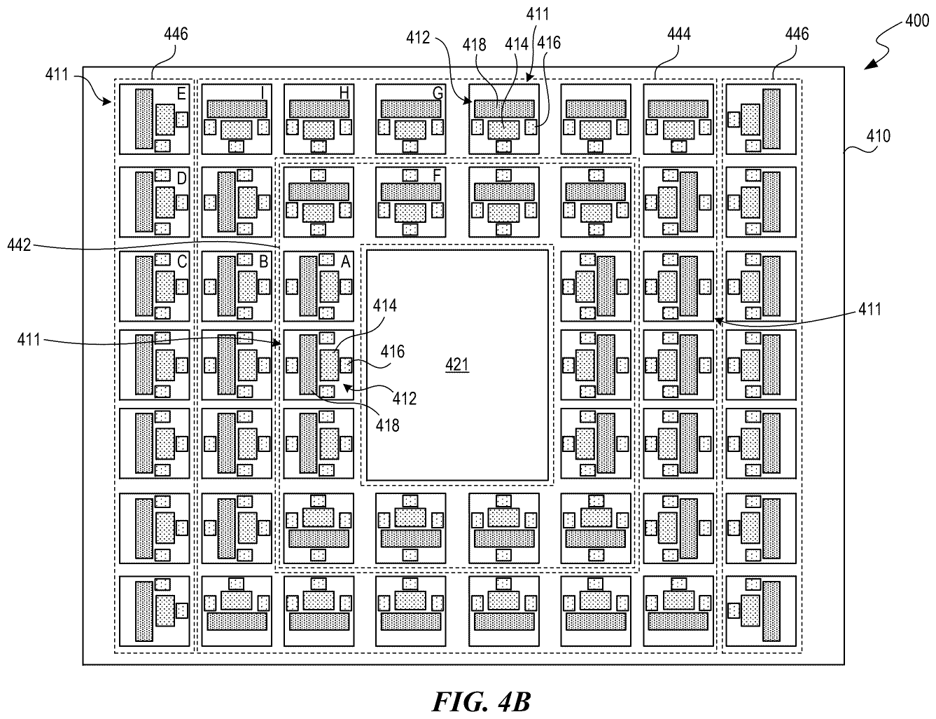

Additional details on examples of the circuit elements in the communication circuits, the HBM cubes, and/or the interposer are discussed below with reference to FIGS. 3A-4B.

FIG. 3A is a partially schematic top plan view of an interface die 332 of an HBM cube 330 configured in accordance with various embodiments of the present technology. The interface die 332 can be generally similar to the interface dies 132 discussed above with reference to FIG. 1A. For example, the interface die 332 can carry (e.g., a stack of) one or more memory dies (e.g., DRAM dies) of the HBM cube 330 and can route signals into and/or out of the HBM cube 330, such as to or from one or more of the memory dies. The interface die 332 includes a communication circuit 334 that allows multiple directions of communication through the interface die 332. For example, the communication circuit 334 (sometimes also referred to herein as a “traffic circuit”) includes a fabric interconnect engine 336 that is coupled to one or more C2C circuits 338 (four illustrated in FIG. 3A). The C2C circuits 338 (sometimes also referred to as “C2C interconnects”) are each couplable to an external component (e.g., a route line in an interposer, a C2C circuit in an adjacent HBM cube, and/or a PHY of a host device) to send and receive signals. The fabric interconnect engine 336, in turn, helps manage traffic through the communication circuit. For example, as discussed in more detail below, when a read request is received at one of the C2C circuits 338, the fabric interconnect engine 336 can look at the address in the read request. If addressed to the HBM cube 330 that includes the interface die 332, the fabric interconnect engine 336 can forward the read request to another component of the HBM cube 330 (e.g., an HBM PHY, a memory controller, an SRAM cache, one or more memory dies, and/or the like). If addressed to a different HBM cube, the fabric interconnect engine 336 can forward the read request through the one of the C2C circuits that received the read request and/or through another one of the C2C circuits 338.

Further, the communication circuits 334 can support a relatively high bandwidth (e.g., generally equal to the bandwidth of the first and second route lines 142, 144 of FIG. 1A). As a result, as discussed in more detail below, the communication circuits 334 can increase the number of HBM cubes available to a host device in a SiP device that incorporates the HBM cube 330. Thus, while each pass through the fabric interconnect engine 336 (sometimes referred to herein as a “hop”) causes a small delay in the signal routing, the communication circuits 334 can increase an amount of memory available to the host device via a high-bandwidth communication channel and/or reduce the number of times data needs to pass through a bottleneck (e.g., a PCI bus coupling the SiP device to a storage device).

For example, FIG. 3B is a partially schematic top plan view of a SiP device 300 that incorporates the HBM cube 330 of FIG. 3A and that is configured in accordance with various embodiments of the present technology. As illustrated in FIG. 3B, the SiP device 300 can be generally similar to the SiP devices 100, 200 discussed above with reference to FIGS. 1A-2. For example, the SiP device 300 includes an interposer 310 (and/or any other suitable base substrate), a host device 320, and a plurality of HBM cubes 330. In the partially schematic top plan view of FIG. 3B, each of the HBM cubes 330 is illustrated showing the components of an interface die 332 discussed above with reference to FIG. 3A. For example, each of the HBM cubes 330 is illustrated with a communication circuit 334 built into the corresponding interface die 332, with each communication circuit 334 including a fabric interconnect engine 336 and one or more C2C circuits 338. It will be understood, however, that interface dies 332 can include various other features (e.g., a PHY, a memory controller, and/or any other suitable circuits). Additionally, it will be understood that each of the HBM cubes 330 can include various other dies (e.g., memory dies and/or any other suitable die) and/or components (e.g., TSVs, metal routing layers, and/or the like) that are not shown in the partially schematic top plan view of FIG. 3B for the sake of clarity and understanding.

As discussed above, the inclusion of the communication circuits 334 in the interface dies 332 allows the SiP device 300 to route signals through the interface dies 332 (e.g., between two or more of the HBM cubes 330 and/or between the host device 320 and one or more of the HBM cubes 330). For example, the SiP device 300 can include a first set 342 of HBM cubes 330 positioned around (partially or fully) a perimeter of the host device 320, and a second set 344 of HBM cubes 330 that is positioned peripheral to the first set 342 from the perspective of the host device 320. Continuing with this example, the SiP device 300 can route signals between one or more HBM cubes 330 of the second set 344 and the host device 320 through at least one HBM cube 330 of the first set 342. The interface dies 332 of the HBM cubes 330 therefore allow a greater number of HBM cubes 330 to be communicably coupled to the host device 320 than in other SiP devices in which a host device is communicatively coupled to only HBM cubes about a perimeter (or on top of) the host device. As a result, the present technology thereby expands the amount of memory available to the host device via a high-bandwidth communication channel. As further illustrated in FIG. 3B, the SiP device 300 is not limited to a single hop between the host device 320 and one of the HBM cubes 330. For example, the SiP device 300 can route signals through HBM cubes 330 and the first and second sets 342, 344 (requiring at least two hops) to reach a third set 346 of the HBM cubes 330 that is positioned peripheral to the second set 344 from the perspective of the host device 320. The additional hops allow the SiP device 300 to communicably couple even larger numbers of the HBM cubes 330 to the host device 320, thereby further expanding the amount of memory available to the host device via a high-bandwidth communication channel.

As further discussed above, the additional amount of memory can allow a larger set of data to be generated, stored, and/or processed onboard the SiP device 300. In turn, the present technology can accelerate computational operations (e.g., AI/ML computing operations) and/or can support more complex computational operations.

As further illustrated in FIG. 3B, in some embodiments, the composition of the communication circuits 334 can vary between the HBM cubes 330. For example, the communication circuits 334 of the interface dies 332 in the first set 342 each include at least four C2C circuits 338 coupled to a corresponding fabric interconnect engine 336. As a result, each of the HBM cubes 330 in the first set 342 can communicate signals in at least four directions. In contrast, because the HBM cubes 330 in the third set 346 (e.g., the outermost/peripheral-most set in the illustrated embodiment) do not need to relay signals to another more peripheral set, the communication circuits 334 of the interface dies 332 in the third set 346 each include less than four of the C2C circuits 338 coupled to a corresponding fabric interconnect engine 336. The omission of superfluous C2C circuits 338 can help reduce a manufacturing cost of the HBM cubes 330 (and therefore the SiP device 300 overall) by reducing the number of unnecessary circuit components. In other embodiments, each of the communication circuits 334 can include a same composition (e.g., a same number of C2C circuits 338).

The multiple C2C circuits 338 in each of the HBM cubes 330 can allow the host device 320 to communicate with HBM cubes 330 in the second and third sets 344, 346 via multiple communication paths. For example, similar to the discussion above with respect to FIG. 2, the host device 320 can communicate with the HBM cube 330 labeled E via a first communication path that includes the HBM cubes 330 labeled A, B, C, and D; via a second communication path that includes the HBM cubes 330 labeled F, G, H, and I; and/or via any other suitable communication path. That is, the multiple C2C circuits 338 in each of the HBM cubes 330 can create some flexibility in how signals are communicated to and/or from the host device 320, thereby allowing the host device 320 to choose communication paths ad hoc based on availability, operability, speed, efficiency, and/or the like.

In some embodiments, the SiP device 300 can include one or more subsets of the HBM cubes 330 that are isolated and/or grouped together. In such embodiments, each of the HBM cubes 330 in the subset includes only the C2C circuits 338 necessary to couple the subset to the host device 320. Further, the host device 320 can only communicate with each of the HBM cubes 330 in the subset via a single communication path. The single, isolated communication path can help simplify addressing and/or signal forwarding at each of the fabric interconnect engines 336, thereby reducing latency associated with each hop. As a result, the single, isolated communication path can be useful for data that will be accessed more often to help reduce the time to access the data. Additionally, or alternatively, the isolated communication path can help ensure that the HBM cubes 330 in the subset are not incorporated into other communication paths. The barrier can be helpful when the HBM cubes 330 in the subset store data that will be accessed more often to help keep the communication circuits 334 in critical HBM cubes available.

In the embodiment illustrated in FIG. 3B, a majority of the C2C circuits 338 are positioned to communicate in square grid directions (e.g., up, down, left, and/or right). It will be understood, however, that the technology disclosed herein is not so limited. For example, the HBM cubes 330 labeled J and I each include diagonal C2C circuits 338 (e.g., to facilitate direct communication between the HBM cubes 330 labeled J and I). The diagonal communication paths can help reduce the number of hops required to access some of the peripheral-most HBM cubes 330 in the SiP device 300. For example, the host device 320 can communicate with the HBM cube 330 labeled E via a third communication path that includes the HBM cubes 330 labeled F, J, and I, thereby reaching the HBM cube 330 labeled E in four hops rather than the five hops required for the first and second communication paths discussed above. Because each hop is associated with some amount of latency in the fabric interconnect engine 336, the reduction in hops can help accelerate the speed of communication and/or the overall operation of the SiP device 300. In various embodiments, the C2C circuits 338 can be positioned in any other suitable orientation and/or with any other suitable number of connections. Additionally, or alternatively, the HBM cubes 330 can include any suitable number of the C2C circuits 338 to increase the number of communication routes available through the SiP device 300 and/or to isolate one or more subsets of the HBM cubes 330.

FIG. 4A is a partially schematic top-plan view of a cube region 411 of an interposer 410 configured in accordance with various embodiments of the present technology. The cube region 411 corresponds to a portion of the interposer 410 in a SiP device that can be integrated with (e.g., support and/or be communicably coupled to) a corresponding HBM cube. Stated another way, the cube region 411 is a portion of the interposer 410 in a SiP device that is positioned at least partially beneath and/or at least partially within a footprint of a corresponding HBM cube when the corresponding HBM cube is stacked on or disposed on the interposer 410. As illustrated in FIG. 4A, the interposer 410 can include a communication circuit 412 formed in the cube region 411 to actively route signals within the interposer 410 and/or to corresponding HBM cubes. The communication circuit 412 can be generally similar to the communication circuits 334 discussed above with reference to FIGS. 3A and 3B. For example, the communication circuit 412 includes a fabric interconnect engine 414 that is coupled to one or more C2C circuits 416 (four illustrated in FIG. 4A). As illustrated in FIG. 4A, the communication circuit 412 additionally includes a PHY 418 (e.g., a JEDEC PHY). As discussed in more detail below, the PHY 418 can be coupled to various components of a corresponding HBM cube. Accordingly, the PHY 418 can be formed in an upper surface of the interposer 410. In addition to the components shown in FIG. 4A, the cube region 411 can include one or more route lines (not shown) coupling the C2C circuits 416 and/or the fabric interconnect engine 414 to the PHY 418.

As discussed above, each of the C2C circuits 416 can be coupled to another component (e.g., a route line in the interposer, the PHY 418, another of the C2C circuits 416 in the cube region 411, a C2C circuit in an adjacent HBM cube, a C2C circuit in an adjacent cube region, the fabric interconnect engine 414 of the cube region 411, and/or a PHY of a host device) to route signals (e.g., between two or more of the HBM cubes and/or between a host device and one or more of the HBM cubes). The fabric interconnect engine 414 can help manage signal traffic through the communication circuit 412. For example, when a read request is received at one of the C2C circuits 416, the fabric interconnect engine 414 can look at the address in the read request. If addressed to an HBM cube corresponding to the cube region 411, the fabric interconnect engine 414 can forward the read request to the PHY 418. In turn, the PHY 418 can help route the read request to an appropriate component within the corresponding HBM cube. In some embodiments, the PHY 418 can replace the PHY in the corresponding HBM cube and can communicate directly with various components of the HBM cube (e.g., a memory controller, an SRAM cache, one or more memory dies, and/or the like). In other embodiments, the PHY 418 is communicably coupled to a PHY in the corresponding HBM cube. In these embodiments, the PHY 418 can forward the read request to the PHY in the corresponding HBM cube. On the other hand, if the read request is addressed to a different HBM cube that does not correspond to the cube region 411, the fabric interconnect engine 414 can forward the read request through the one of the C2C circuits 416 that received the read request and/or through another one of the C2C circuits 416 of the communication circuit 412.

Forming the communication circuit 412 directly in the interposer 410 can take advantage of available, otherwise idle space in the interposer 410. Further, forming the communication circuit 412 in the interposer 410 instead of, for example, an interface die (or another die) of an HBM cube can save space in the interface die and/or facilitate omitting the interface die. Saving space in the interface die can allow other components to be formed in the interface die, such as additional cache memory, memory controllers, processors, and/or the like. Omitting the interface die can facilitate reducing a size (e.g., a height) of a corresponding SiP device. Additionally, or alternatively, forming the communication circuit 412 in the interposer 410 instead of in the interface die can reduce (or eliminate) changes to a manufacturing process of the HBM cube and/or simplify the connection of routing components (e.g., TSVs) within the HBM cube.

FIG. 4B is a partially schematic top plan view of a SiP device 400 that includes a plurality of cube regions 411 of the type illustrated in FIG. 4A and that is configured in accordance with various embodiments of the present technology. As illustrated, the SiP device 400 can be generally similar to the SiP devices 100, 200, 300 discussed above with reference to FIGS. 1A-3B. For example, the SiP device 400 can include an interposer 410 (and/or any other suitable base substrate). The interposer 410 of FIG. 4B includes a host device region 421 and a plurality of cube regions 411 surrounding the host device region 421. It will be understood that, when the SiP device 400 is packaged, the host device region 421 can be integrated with a host device and each of the cube regions 411 can be integrated with a corresponding HBM cube. The host device and the corresponding HBM cubes are omitted from FIG. 4B, however, to avoid obscuring aspects of the present technology (e.g., aspects of the interposer 410). As illustrated in FIG. 4B, each of the cube regions 411 includes a communication circuit 412 formed therein. Further, as discussed above with reference to FIG. 4A, each of the communication circuits 412 includes including a fabric interconnect engine 414, one or more C2C circuits 416, and a PHY 418.

As discussed above, the inclusion of the communication circuits 412 in the interposer 410 allows the SiP device 400 to route signals through each of the cube regions 411 (and therefore through a footprint of one or more corresponding HBM cubes when carried by the interposer 410). For example, the SiP device 400 can route signals through a first set 442 of the cube regions 411 that includes cube regions 411 positioned around (partially or fully) a perimeter of the host device region 421 (e.g., in the beachfront locations) to a second set 444 of the cube regions 411 that includes cube regions 411 positioned peripheral to the first set 442 from the perspective of the host device region of 421. As a result, the cube regions 411 therefore allow a greater number of HBM cubes to be communicably coupled to a host device integrated with the host device region 421 than in other SiP devices in which a host device is communicably coupled to HBM cubes about a perimeter (or on top of) the host device. As discussed above, the increase in the number of HBM cubes that can be coupled to the host device can expand the amount of memory available to the host device via a high-bandwidth communication channel, thereby improving speeds of data-intensive computing operations.

As further illustrated in FIG. 4B, the SiP device 400 is not limited to a single hop between the host device region 421 and one of the cube regions 411. For example, to communicate with an HBM cube coupled to a cube region 411 in a third set 446 of the cube regions 411 that includes cube regions 411 positioned peripheral to cube regions 411 of the second set 442 from the perspective of the host device region 421, the SiP device 400 can route signals through one or more cube regions 411 of the first set 442 and one or more cube regions 411 of the second set 444. The additional hops allow the SiP device 400 to communicably couple even larger numbers of the cube regions 411 to the host device region 421, thereby further expanding the amount of memory available to a host device via a high-bandwidth communication channel. In various embodiments, the SiP device 400 can also include a fourth set (not shown) of the cube regions 411 that is peripheral to the third set 446 (from the perspective of the host device region 421) and coupled to the host device region 421 through cube regions 411 of the first set 442, the second set 444, and the third set 446; a fifth set (not shown) that is peripheral to the fourth set (from the perspective of the host device region 421) and coupled to host device region 421 through cube regions 411 of the first, second, third, and fourth sets; and so on for any suitable number of sets. Further, it will be understood that the sets can have any other suitable arrangement of the cube regions 411. For example, the third set 446 can include one or more cube regions 411 positioned above (or below) the cube regions 411 of the second set 444. That is, the third set 446 can include a row of the cube regions 411 above (or below) the top (or bottom) row of the cube regions 411 of the second set 444.

Similar to the discussion above, the C2C circuits 416 in each of the cube regions 411 can allow a host device that is integrated with the host device region 421 to communicate with HBM cubes integrated with one or more of the cube regions 411 in the first, second, and/or third sets 442, 444, 446 via multiple communication paths. For example, the host device can communicate with the cube region 411 labeled E via a first communication path that includes the cube regions 411 labeled A, B, C, and D; via a second communication path that includes the cube regions 411 labeled F, G, H, and I; and/or via any other suitable communication path. That is, the C2C circuits 416 in each of the cube regions 411 can create some flexibility in how signals are communicated to and/or from the host device, thereby allowing the host device to choose communication paths ad hoc based on availability, operability, speed, efficiency, and/or the like.

As further illustrated in FIG. 4B, the composition of the communication circuits 412 can vary between different cube regions 411. For example, the communication circuit 412 in the cube regions 411 labeled A can include four C2C circuits 416 coupled to a corresponding fabric interconnect engine 414. As a result, the cube regions 411 labeled A can communicate signals in at least four directions. In contrast, the cube regions 411 labeled D and E each include less than four of the C2C circuits 416 coupled to a corresponding fabric interconnect engine 414 (e.g., because these cube regions 411 do not need to relay signals to more peripheral cube regions 411). The omission of C2C circuits 416 in these cube regions 411 can help reduce a manufacturing cost of the interposer 410 (and therefore the SiP device 400 overall) by reducing the number of circuit components. Further, as discussed above, it can be useful to isolate one or more subsets of the cube regions 411 (e.g., to establish a permanent, exclusive communication path for HBM cubes storing data that will be accessed often). Accordingly, it will be understood that the SiP device 400 can include one or more subsets of the cube regions 411 that are isolated and/or grouped together. In such embodiments, each of the cube regions 411 in the subset can include only the C2C circuits 416 necessary to couple the subset to the host device region 421, thereby creating a single isolated communication path between the corresponding HBM cubes and the host device. In other embodiments, each of the communication circuits 412 can include a same composition (e.g., a same number of C2C circuits 416).

Furthermore, while a majority of the C2C circuits 416 illustrated in FIG. 4B are positioned to communicate in square grid directions (e.g., up, down, left, and/or right), it will be understood that the technology disclosed herein is not so limited. For example, the cube regions 411 can include diagonally positioned C2C circuits (e.g., similar to the diagonal C2C circuits 338 of the HBM cubes 330 labeled I and J discussed above with reference to FIG. 3B) that can help reduce the number of hops required to access peripheral cube regions 411 (e.g., of the second and/or third sets 444, 446) in the SiP device 400. Because each hop is associated with some amount of latency in the fabric interconnect engine 414, the reduction in hops can help accelerate the speed of communication and/or the overall operation of the SiP device 400. Additionally, or alternatively, the cube regions 411 can include C2C circuits 416 that are positioned in any other suitable orientation, in any other suitable arrangement with respect to the corresponding fabric interconnect engine 414 and/or PHY 418, and/or with any other suitable number of connections. For example, as illustrated in FIG. 4B, various cube regions 411 can be rotated with respect to each other. In the specific, non-limiting example illustrated in FIG. 4B, the cube regions 411 on the right side of the host device region 421 are generally rotated about 180 degrees with respect to the cube regions 411 on the left side of the host device region 421. In various other examples, the cube regions 411 can be rotated in any other suitable arrangement to form a variety of communication routes through the interposer 410. Additionally, or alternatively, the cube regions 411 can include any suitable number of the C2C circuits 416 to increase the number of communication routes available through the SiP device 400 and/or to isolate one or more subsets of the cube regions 411.

### Conclusion

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Further, the terms “approximately” and “about” are used herein to mean within at least within 10% of a given value or limit. Purely by way of example, an approximate ratio means within 10% of the given ratio.

Several implementations of the disclosed technology are described above in reference to the figures. The computing devices on which the described technology may be implemented can include one or more central processing units, memory, input devices (e.g., keyboard and pointing devices), output devices (e.g., display devices), storage devices (e.g., disk drives), and network devices (e.g., network interfaces). The memory and storage devices are computer-readable storage media that can store instructions that implement at least portions of the described technology. In addition, the data structures and message structures can be stored or transmitted via a data transmission medium, such as a signal on a communications link. Various communications links can be used, such as the Internet, a local area network, a wide area network, or a point-to-point dial-up connection. Thus, computer-readable media can comprise computer-readable storage media (e.g., “non-transitory” media) and computer-readable transmission media.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments.

Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A system-in-package (“SiP”) device, comprising:
an interposer;
a host device coupled to a first side of the interposer;
a first set of high-bandwidth memory (HBM) cubes, each HBM cube of the first set coupled to the first side of the interposer; and
a second set of HBM cubes different from the first set of HBM cubes, each HBM cube of the second set coupled to the first side of the interposer, wherein:
the HBM cubes of the first set are positioned around a perimeter of the host device and are coupled to the host device through the interposer, and
the HBM cubes of the second set are positioned such that the first set of HBM cubes are electrically positioned between the HBM cubes of the second set and the host device.

2. The SiP device of claim 1, further comprising a plurality of communication circuits configured to selectively couple each of the HBM cubes of the second set to the host device through a footprint of at least one HBM cube of the first set.

3. The SiP device of claim 2, wherein each of the HBM cubes includes a base die and a stack of memory dies carried by the base die, and each base die includes an individual one of the plurality of communication circuits, and wherein each of the communication circuits includes a fabric interconnect engine and a plurality of chip-to-chip (C2C) circuits.

4. The SiP device of claim 2, wherein the plurality of communication circuits are formed in the interposer, and wherein each of the communication circuits includes a fabric interconnect engine and a plurality of chip-to-chip (C2C) circuits.

5. The SiP device of claim 4, wherein each of the communication circuits further includes a physical layer (PHY) circuit.

6. The SiP device of claim 1, wherein a first HBM cube of the second set is configured to communicate with the host device through a footprint of a second HBM cube of the SiP device.

7. The SiP device of claim 6, wherein a base die of the second HBM cube includes two or more chip-to-chip (C2C) circuits and a corresponding fabric interconnect engine.

8. The SiP device of claim 6, wherein the second HBM cube is of the second set, and wherein the first HBM cube is further configured to communicate with the host device through a footprint of a third HBM cube of the first set.

9. The SiP device of claim 6, further comprising a third set of HBM cubes different from the first and second sets of HBM cubes, wherein each HBM cube of the third set is coupled to the first side of the interposer, wherein HBM cubes of the third set are positioned such that the HBM cubes of the first set and the second set are electrically positioned between the HBM cubes of the third set and the host device.

10. The SiP device of claim 1, wherein each of the HBM cubes of the first set is positioned immediately about the perimeter of the host device.

11. A semiconductor device, comprising:
an interposer having an upper surface;
a host device disposed on the upper surface; and
a plurality of high-bandwidth memory (HBM) cubes disposed on the upper surface, wherein the plurality of HBM cubes includes a first HBM cube and a second HBM cube, and wherein:
the first HBM cube comprises an interface die and one or more memory dies carried by the interface die, wherein the interface die includes a communication circuit having a fabric interconnect engine and two or more chip-to-chip (C2C) circuits, and
the second HBM cube is communicably couplable to the host device through the communication circuit of the first HBM cube.

12. The semiconductor device of claim 11 wherein:
the plurality of HBM cubes further includes a third HBM cube, wherein the third HBM cube comprises an interface die and one or more memory dies carried by the interface die, and wherein the interface die of the third HBM cube includes a communication circuit having a fabric interconnect engine and two or more C2C circuits; and
the second HBM cube is communicably couplable to the host device through the communication circuit of the third HBM cube.

13. The semiconductor device of claim 12, wherein, to communicate with the second HBM device, the host device is configured to select between utilizing the communication circuit of the first HBM cube and the communication circuit of the third HBM cube.

14. The semiconductor device of claim 11, wherein the first HBM cube is positioned between the second HBM cube and the host device.

15. An interposer for a system-in-package device, the interposer comprising:
a processing region couplable to a host device and having a perimeter;
a first cube region positioned adjacent the perimeter of the processing region, wherein the first cube region includes a first communication circuit couplable to a first HBM cube, and wherein the first communication circuit is coupled to the processing region; and
a second cube region positioned peripheral to the first cube region with respect to the processing region, wherein the second cube region includes a second communication circuit couplable to a second HBM cube, and wherein the second communication circuit is couplable to the processing region through the first communication circuit.

16. The interposer of claim 15 wherein the first communication circuit comprises:
a fabric interconnect engine; and
a plurality of chip-to-chip (C2C) circuits, wherein at least one of the plurality of C2C circuits is coupled to the processing region.

17. The interposer of claim 16, wherein the first communication circuit further comprises a physical layer (PHY) couplable to the first HBM cube, and wherein the PHY is configured to route signals to one or more memory dies in the first HBM cube when the first HBM cube is coupled to the first communication circuit.

18. The interposer of claim 15, wherein the interposer further comprises a third cube region positioned adjacent to the perimeter of the processing region, wherein the third cube region includes a third communication circuit couplable to a third HBM cube, wherein the third cube region is coupled to the processing region, and wherein the second communication circuit is couplable to the processing region through the third communication circuit.

19. The interposer of claim 15, further comprising a third cube region positioned peripheral to the second cube region with respect to the processing region, wherein the third cube region includes a third communication circuit couplable to a third HBM cube, wherein the third communication circuit is couplable to the processing region through the second communication circuit and the first communication circuit.

20. The interposer of claim 15, wherein the first cube region is one of a first set of cube regions positioned around the perimeter of the processing region, and wherein the second cube region is one of a second set of cube regions positioned around the perimeter of the processing region peripheral to the first set of cube regions with respect to the processing region.
